(19) United States
(12) Patent Application Publication
(10) Pub. No.: US 2025/0276522 A1
(43) Pub. Date: Sep. 4, 2025

(54) LIQUID EJECTING HEAD

(71) Applicant: SEIKO EPSON CORPORATION, Tokyo (JP)

(72) Inventors: Harunobu KOIKE, MATSUMOTO-SHI (JP); Toshihiro SHIMIZU, FUJIMI-MACHI (JP); Takatoshi YAMAZAKI, SHIOJIRI-SHI (JP)

(21) Appl. No.: 19/068,082

(22) Filed: Mar. 3, 2025

(30) Foreign Application Priority Data
Mar. 4, 2024 (JP) 2024-031944

(51) Int. Cl. B41J 2/14; H10N 30/85; H10N 30/87

(52) U.S. Cl. CPC B41J 2/14233; H10N 30/85; H10N 30/877; B41J 2002/14258

(57) ABSTRACT

A liquid ejecting head includes a piezoelectric element including an individual electrode, a piezoelectric layer, and a common electrode, and a vibration plate, and the individual electrode is individually provided for each of a plurality of the piezoelectric elements, the common electrode is provided in common for the plurality of piezoelectric elements, the piezoelectric layer is made of a piezoelectric material containing lead as a constituent element, each of the individual electrode and the common electrode contains lead, and a lead content in the common electrode is lower than a lead content in the individual electrode.

The present application is based on, and claims priority from JP Application Serial Number 2024-031944, filed Mar. 4, 2024, the disclosure of which is hereby incorporated by reference herein in its entirety.

### BACKGROUND

### 1. Technical Field

The present disclosure relates to a liquid ejecting head.

### 2. Related Art

In a liquid ejecting apparatus represented by a piezoelectric ink jet printer, a liquid ejecting head that ejects a liquid such as ink is used. For example, the head described in JP-A-2002-319714 includes a vibration plate and a piezoelectric element. The piezoelectric element includes a lower electrode, a piezoelectric film, and an upper electrode that are sequentially stacked on the vibration plate.

In the head described in JP-A-2002-319714, the relationship between the lead contents of the lower and upper electrodes is not considered, and there is room for improvement.

### SUMMARY

In order to solve the above-described problem, according to an aspect of the present disclosure, there is provided a liquid ejecting head including a piezoelectric element including an individual electrode, a piezoelectric layer, and a common electrode, and a vibration plate, in which the individual electrode is individually provided for each of a plurality of piezoelectric elements, the common electrode is provided in common for the plurality of piezoelectric elements, the piezoelectric layer is made of a piezoelectric material containing lead as a constituent element, each of the individual electrode and the common electrode contains lead, and a lead content in the common electrode is lower than a lead content in the individual electrode.

### BRIEF DESCRIPTION OF THE DRAWINGS

FIG. 1 is a configuration diagram schematically illustrating a liquid ejecting apparatus including a liquid ejecting head according to a first embodiment.

FIG. 2 is an exploded perspective view of a liquid ejecting head according to the first embodiment.

FIG. 3 is a sectional view taken along line III-III in FIG. 2.

FIG. 4 is a plan view illustrating a part of the liquid ejecting head according to the first embodiment.

FIG. 5 is a sectional view taken along line V-V in FIG. 4.

FIG. 6 is an enlarged view of a portion VI in FIG. 5.

FIG. 7 is a schematic sectional view of a liquid ejecting head according to a second embodiment.

FIG. 8 is an enlarged view of a portion VIII in FIG. 7.

### DESCRIPTION OF EMBODIMENTS

Hereinafter, preferred embodiments according to the present disclosure will be described with reference to the attached drawings. In the drawings, the dimension and scale of each portion are different from the actual ones as appropriate, and some portions are schematically illustrated to facilitate understanding. In addition, the scope of the present disclosure is not limited to these embodiments unless otherwise stated to limit the present disclosure in the following description.

The following description uses an X axis, a Y axis, and a Z axis that intersect with each other as appropriate. In addition, in the following description, one direction along the X axis is an X1 direction, and the direction opposite to the X1 direction is an X2 direction. Similarly, directions opposite to each other along the Y axis are a Y1 direction and a Y2 direction. Moreover, directions opposite to each other along the Z axis are a Z1 direction and a Z2 direction. The Z1 direction is an example of a “stacking direction”. In addition, viewing in the direction along the Z axis may be referred to as “plan view”.

Here, typically, the Z axis is a vertical axis, and the Z2 direction corresponds to a vertically downward direction. However, the Z axis does not have to be the vertical axis. In addition, the X axis, the Y axis, and the Z axis are typically orthogonal to each other, but are not limited thereto. For example, the X axis, the Y axis, and the Z axis may intersect with each other at an angle in a range of 80° or more and 100° or less.

### 1. Embodiment

### 1-1. Overall Configuration of Liquid Ejecting Apparatus

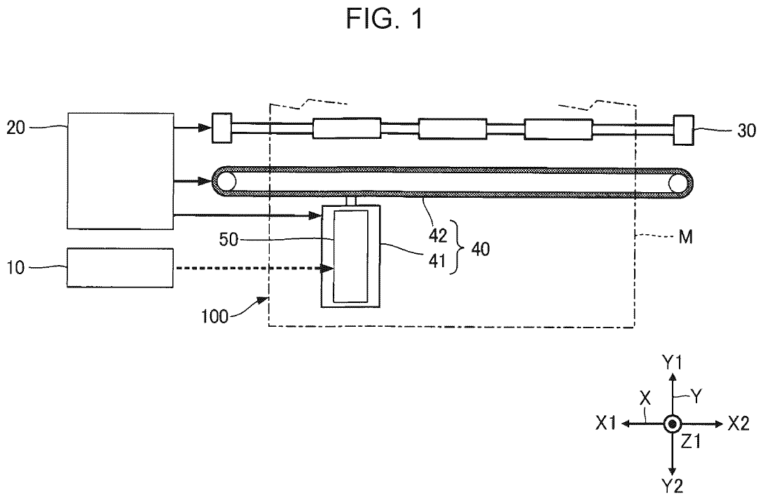

FIG. 1 is a configuration diagram schematically illustrating a liquid ejecting apparatus 100 including a liquid ejecting head 50 according to a first embodiment. The liquid ejecting apparatus 100 is an ink jet printing apparatus that ejects ink, which is an example of a liquid, as droplets onto a medium M. The medium M is typically a printing paper sheet. The medium M is not limited to the printing paper sheet and may be a printing target made of any material such as a resin film or a fabric.

As illustrated in FIG. 1, the liquid ejecting apparatus 100 includes a liquid container 10, a control unit 20, a transport mechanism 30, a moving mechanism 40, and a liquid ejecting head 50.

The liquid container 10 is a container that stores ink. Examples of the specific form of the liquid container 10 include a cartridge attachable to and detachable from the liquid ejecting apparatus 100, a bag-shaped ink pack formed of a flexible film, and an ink tank refillable with the ink. A type of ink to be stored in the liquid container 10 is not particularly limited and is selected in any desired way.

The control unit 20 includes, for example, a processing circuit such as a central processing unit (CPU) or a field-programmable gate array (FPGA) and a storage circuit such as a semiconductor memory to control the operation of each element of the liquid ejecting apparatus 100.

The transport mechanism 30 transports the medium M in the Y2 direction under the control of the control unit 20. The moving mechanism 40 causes the liquid ejecting head 50 to reciprocate in the X1 direction and the X2 direction under the control of the control unit 20. In the example illustrated FIG. 1, the moving mechanism 40 includes a substantially box-shaped carriage 41 that accommodates the liquid ejecting head 50, and a transport belt 42 to which the carriage 41 is fixed. The number of liquid ejecting heads 50 mounted in the carriage 41 is not limited to one and may be two or more. Moreover, in addition to the liquid ejecting head 50, the above-described liquid container 10 may be mounted in the carriage 41.

The liquid ejecting head 50 ejects the ink supplied from the liquid container 10 onto the medium M in the Z2 direction from each of a plurality of nozzles under the control of the control unit 20. The ejection is performed in parallel with the transport of the medium M by the transport mechanism 30 and the reciprocating movement of the liquid ejecting head 50 by the moving mechanism 40, and thus an image is formed by the ink on a surface of the medium M.

### 1-2. Overall Configuration of Liquid Ejecting Head

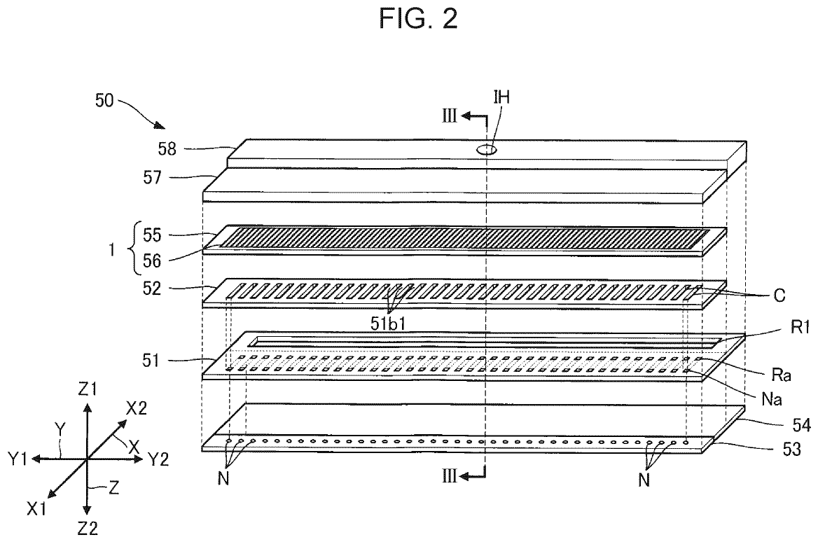

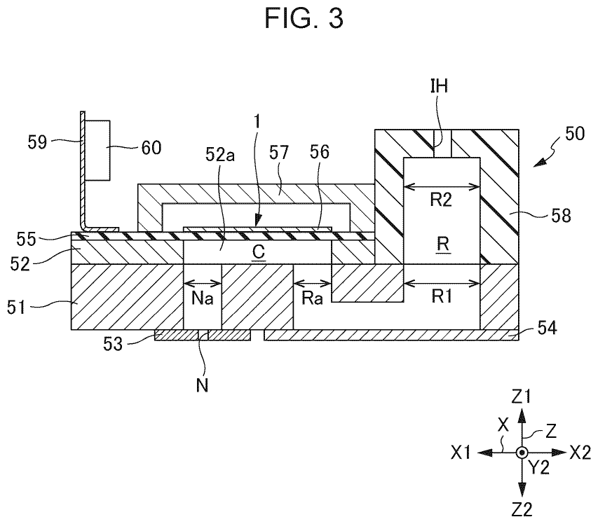

FIG. 2 is an exploded perspective view of the liquid ejecting head 50 according to the first embodiment. FIG. 3 is a sectional view taken along line III-III in FIG. 2. As illustrated in FIGS. 2 and 3, the liquid ejecting head 50 includes a flow path substrate 51, a pressure chamber substrate 52, a nozzle plate 53, a vibration absorber 54, a vibration plate 55, a plurality of piezoelectric elements 56, a sealing plate 57, a case 58, and a wiring substrate 59. The vibration plate 55 and the piezoelectric elements 56 constitute an actuator 1. In this manner, the liquid ejecting head 50 includes the actuator 1 including the piezoelectric elements 56 and the vibration plate 55.

Here, the pressure chamber substrate 52, the vibration plate 55, the plurality of piezoelectric elements 56, the case 58, and the sealing plate 57 are installed in a region located further in the Z1 direction than is the flow path substrate 51. On the other hand, the nozzle plate 53 and the vibration absorber 54 are installed in a region located further in the Z2 direction than is the flow path substrate 51. The elements of the liquid ejecting head 50 are generally plate-like members elongated in a direction along the Y axis and are bonded to each other with, for example, an adhesive.

As illustrated in FIG. 2, the nozzle plate 53 is a plate-like member provided with a plurality of nozzles N arranged in the direction along the Y axis. Each of the nozzles Nis a through-hole through which the ink passes. In this manner, the nozzle plate 53 has the plurality of nozzles N that ejects the ink. The nozzle plate 53 is manufactured, for example, through processing of a silicon single crystal substrate by a semiconductor manufacturing technique using a processing technique such as dry etching or wet etching. However, other known methods and materials may be appropriately used to manufacture the nozzle plate 53.

The flow path substrate 51 is a plate-like member for forming a flow path for the ink. As illustrated in FIGS. 2 and 3, an opening portion R1, a plurality of supply flow paths Ra, and a plurality of communication flow paths Na are provided in the flow path substrate 51. The opening portion R1 is an elongated through-hole extending in the direction along the Y axis in plan view in the direction along the Z axis so as to be continuous over the plurality of nozzles N. On the other hand, each of the supply flow paths Ra and the communication flow paths Na is a through-hole provided individually for each of the nozzles N. Each of the plurality of supply flow paths Ra is in communication with the opening portion R1. Similarly to the above-described nozzle plate 53, the flow path substrate 51 is manufactured, for example, through processing of a silicon single crystal substrate by a semiconductor manufacturing technique. However, other known methods and materials may be appropriately used to manufacture the flow path substrate 51.

The pressure chamber substrate 52 is a plate-like member in which a plurality of pressure chambers C corresponding to the nozzles N is formed. Each of the pressure chambers C is located between the flow path substrate 51 and the vibration plate 55 and is a space called a cavity for applying pressure to the ink filled in the pressure chamber C. The plurality of pressure chambers C is arranged in the direction along the Y axis. Each of the pressure chambers C is formed from a hole 52a that is open to both surfaces of the pressure chamber substrate 52 and has an elongated shape extending in a direction along the X axis. In this manner, the pressure chamber substrate 52 has the plurality of pressure chambers C in communication with the nozzles N. An end of each pressure chamber C in the X2 direction is in communication with the corresponding supply flow path Ra. On the other hand, an end of each pressure chamber C in the X1 direction is in communication with the corresponding communication flow path Na. Similarly to the above-described nozzle plate 53, the pressure chamber substrate 52 is manufactured, for example, through processing of a silicon single crystal substrate by a semiconductor manufacturing technique. However, other known methods and materials may be appropriately used to manufacture the pressure chamber substrate 52.

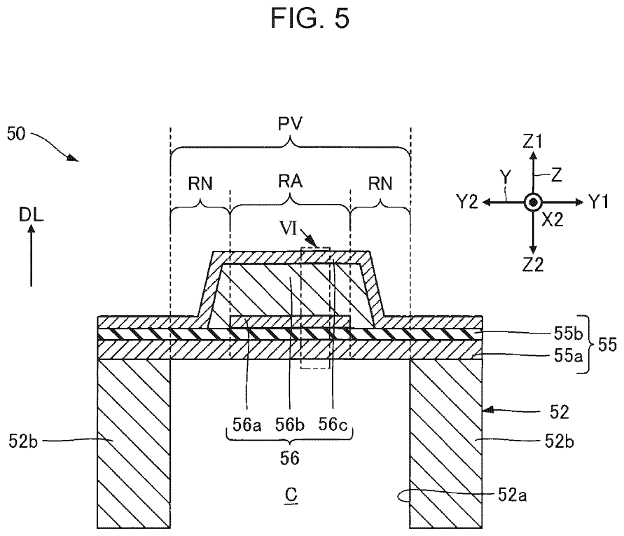

The vibration plate 55 is installed on a surface of the pressure chamber substrate 52 facing in the Z1 direction. The vibration plate 55 is an elastically deformable plate-like member and is connected to the piezoelectric elements 56. Details of the vibration plate 55 will be described later with reference to FIG. 5.

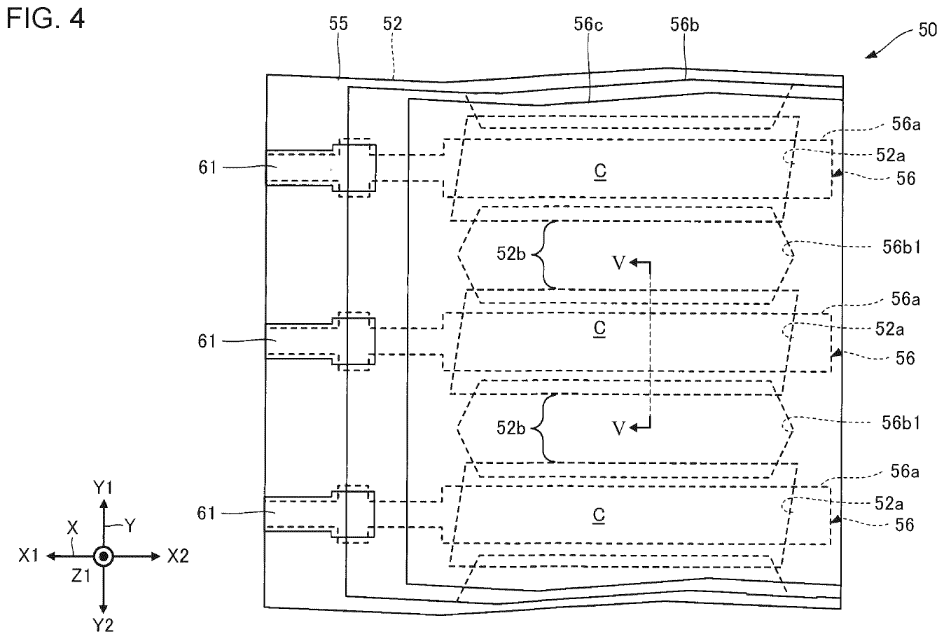

The piezoelectric elements 56 are disposed on a surface of the vibration plate 55 facing in the Z1 direction. Each of the piezoelectric elements 56 is a passive element that is deformed by a supplied drive signal and has an elongated shape extending in the direction along the X axis. One piezoelectric element 56 is provided for each pressure chamber, and the plurality of piezoelectric elements 56 is arranged in the direction along the Y axis so as to correspond to the plurality of pressure chambers C. When the vibration plate 55 vibrates along with the deformation of the piezoelectric elements 56, the pressure in the pressure chambers C fluctuates, which causes the ink to be ejected from the nozzles N. Details of the piezoelectric elements 56 will be described later with reference to FIGS. 4 to 6.

The case 58 is a case for storing the ink to be supplied to the plurality of pressure chambers C and is bonded to a surface of the flow path substrate 51 facing in the Z1 direction with an adhesive or the like. The case 58 is made of, for example, a resin material and is manufactured by injection molding. The case 58 includes an accommodation portion R2 and an introduction port IH. The accommodation portion R2 is a recessed portion having an outer shape corresponding to the opening portion R1 of the flow path substrate 51. The introduction port IH is a through-hole in communication with the accommodation portion R2. A space formed by the opening portion R1 and the accommodation portion R2 functions as a liquid storage chamber R that is a reservoir for storing the ink. The ink from the liquid container 10 is supplied to the liquid storage chamber R through the introduction port IH.

The vibration absorber 54 is an element that absorbs pressure fluctuations in the liquid storage chamber R. The vibration absorber 54 is, for example, a compliance substrate that is an elastically deformable and flexible sheet member. Here, the vibration absorber 54 is disposed on a surface of the flow path substrate 51 facing in the Z2 direction to close the opening portion R1 and the plurality of supply flow paths Ra of the flow path substrate 51 and thus form a bottom surface of the liquid storage chamber R.

The sealing plate 57 is a structure that protects the plurality of piezoelectric elements 56 and reinforces the mechanical strength of the pressure chamber substrate 52 and the vibration plate 55. The sealing plate 57 is bonded to a surface of the vibration plate 55 with, for example, an adhesive. The sealing plate 57 includes a recessed portion that accommodates the plurality of piezoelectric elements 56.

The wiring substrate 59 is bonded to the surface of the pressure chamber substrate 52 or the vibration plate 55 facing in the Z1 direction. The wiring substrate 59 is a mounting component on which a plurality of wiring lines is formed to electrically couple the control unit 20 and the liquid ejecting head 50. The wiring substrate 59 is a flexible wiring substrate such as a flexible printed circuit (FPC) or a flexible flat cable (FFC). A drive circuit 60 for driving the piezoelectric elements 56 is mounted on the wiring substrate 59. The drive circuit 60 selectively supplies a drive signal for driving each piezoelectric element 56 to each piezoelectric element 56 via the wiring substrate 59.

### 1-3. Details of Vibration Plate and Piezoelectric Element

FIG. 4 is a plan view illustrating an example of the liquid ejecting head 50 according to the first embodiment. FIG. 5 is a sectional view taken along line V-V in FIG. 4. Hereinafter, the pressure chamber substrate 52, the piezoelectric element 56, and the vibration plate 55 will be described in this order with reference to FIGS. 4 and 5.

As illustrated in FIGS. 4 and 5, the hole 52a constituting each of the pressure chambers C is provided in the pressure chamber substrate 52. Accordingly, a wall-shaped partition 52b extending in the direction along the X axis is provided between two holes 52a adjacent to each other in the pressure chamber substrate 52. The pressure chamber substrate 52 is manufactured, for example, through processing of a silicon single crystal substrate by a semiconductor manufacturing technique. In FIG. 4, the shape in plan view of each hole 52a formed through anisotropically etching of a silicon single crystal substrate having a plane orientation (110) is indicated by a broken line. The shape of the hole 52a in plan view is not limited to the example illustrated in FIG. 4 and is selected in any desired way.

Here, the pressure chamber C is formed after the piezoelectric element 56 is formed. The pressure chamber C is formed through, for example, anisotropically etching of a surface different from the surface on which the piezoelectric element 56 is formed, of both surfaces of the silicon single crystal substrate, after the piezoelectric element 56 is formed. At this time, as an etchant of the anisotropic etching, for example, a potassium hydroxide aqueous solution (KOH) or the like is used. In addition, at this time, when an elastic layer 55a is made of silicon oxide, the elastic layer 55a functions as a stopping layer for stopping the anisotropic etching. After the pressure chamber C described above is formed, the flow path substrate 51 and the like are bonded to the pressure chamber substrate 52 with an adhesive. After the piezoelectric element 56 is formed, if necessary, the surface opposite to the surface on which the piezoelectric element 56 is formed, of both surfaces of the silicon single crystal substrate, is ground by chemical mechanical polishing (CMP) or the like so that the surface is planarized, or the thickness of the substrate is adjusted.

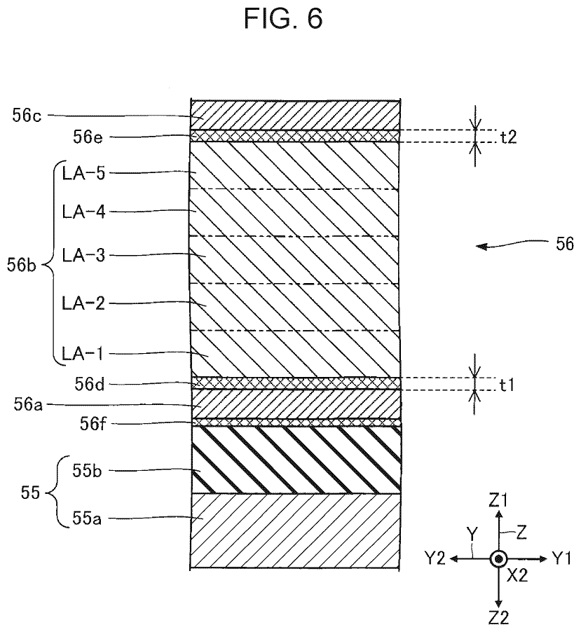

As illustrated in FIG. 4, the piezoelectric element 56 overlaps with the pressure chamber C in plan view. As illustrated in FIG. 5, the piezoelectric element 56 includes an individual electrode 56a, a piezoelectric layer 56b, and a common electrode 56c in this order. In the present embodiment, the individual electrode 56a, the piezoelectric layer 56b, and the common electrode 56c are stacked in order in the Z1 direction. That is, the individual electrode 56a, the piezoelectric layer 56b, and the common electrode 56c are stacked in this order in a stacking direction DL, which is a direction from the vibration plate 55 toward the piezoelectric element 56. As will be described later with reference to FIG. 6, the piezoelectric element 56 includes a first mixed layer 56d, a second mixed layer 56e, and a lead diffusion suppression layer 56f in addition to the individual electrode 56a, the piezoelectric layer 56b, and the common electrode 56c. Hereinafter, in the present embodiment, the individual electrode 56a may be referred to as a “lower electrode”, and the common electrode 56c may be referred to as an “upper electrode”.

The individual electrode 56a is an electrode individually provided for each of the plurality of piezoelectric elements 56. Specifically, a plurality of the individual electrodes 56a extending in the direction along the X axis is arranged in the direction along the Y axis at an interval from each other. A drive signal including a predetermined voltage pulse is supplied from the control unit 20 to each individual electrode 56a of each piezoelectric element 56.

The individual electrode 56a includes, for example, a layer made of platinum (Pt), a layer made of iridium (Ir), and a layer made of titanium (Ti). That is, the individual electrode 56a contains platinum, iridium, and titanium. Here, platinum is an electrode material having excellent conductivity. Therefore, through using of platinum as the constituent material of the individual electrode 56a, the resistance of the individual electrode 56a can be reduced. In addition, when the piezoelectric layer 56b is formed, in the layer made of titanium, island-shaped titanium serves as a crystal nucleus to control the orientation of the piezoelectric layer 56b, thereby improving the crystallinity or the orientation of the piezoelectric layer 56b. Instead of these layers or in addition to these layers, a layer made of another metal material or a conductive oxide may be provided. In addition, these layers may have a layer in which a plurality of metal materials are mixed or alloyed.

In this manner, the individual electrode 56a is mainly made of an electrode material having excellent conductivity, but contains a small amount of lead. When lead is contained in the individual electrode 56a as described above, the Young's modulus of the individual electrode 56a can be reduced, and the adhesion between the individual electrode 56a and the piezoelectric layer 56b can be improved. Hereinafter, the material constituting the individual electrode 56a may be referred to as a “first electrode material”.

The individual electrode 56a described above is formed by, for example, a known film forming technique such as a sputtering method and a known processing technique using photolithography, etching, and the like after the vibration plate 55 is formed. In addition, the individual electrode 56a may contain lead through, for example, introducing of lead by ion implantation or forming of a film of a material containing lead, although not particularly limited thereto. In addition, a thickness of the individual electrode 56a is, for example, approximately 100 nm.

In the example illustrated in FIGS. 4 and 5, the piezoelectric layer 56b has a band shape extending in the direction along the Y axis so as to be continuous over the plurality of piezoelectric elements 56. In the example illustrated in FIG. 4, the piezoelectric layer 56b includes a through-hole 56b1 extending through the piezoelectric layer 56b and extending in the direction along the X axis in a region corresponding to a gap between the adjacent pressure chambers C in plan view. As a result, the piezoelectric layer 56b is individually provided for each piezoelectric element 56 in the sectional view illustrated in FIG. 5. The piezoelectric layer 56b may be individually provided for each of the plurality of piezoelectric elements 56.

The piezoelectric layer 56b is made of a piezoelectric material containing lead as a constituent element. The piezoelectric material has a perovskite crystal structure represented by the general composition formula ABO₃ and is, for example, lead zirconate titanate (Pb(Zr,Ti)O₃). In addition, the piezoelectric layer 56b may contain at least one element of vanadium (V), niobium (Nb), tantalum (Ta), phosphorus (P), arsenic (As), antimony (Sb), and bismuth (Bi) in addition to lead (Pb). Lead contained in the piezoelectric material constituting the piezoelectric layer 56b may be an element that does not constitute a part of the perovskite crystal structure.

The piezoelectric layer 56b described above is formed through, for example, uniformly forming of a precursor layer of a piezoelectric body by a sol-gel method after the individual electrode 56a is formed, firing and crystallizing of the precursor layer, and then patterning of the precursor layer by etching such as reactive ion etching (RIE) or ion milling. In the present embodiment, as will be described later, the piezoelectric layer 56b includes a plurality of layers LA, and the plurality of layers LA is formed through repeating of forming and firing of the above-described precursor.

The common electrode 56c is an electrode provided in common for the plurality of piezoelectric elements 56. Specifically, the common electrode 56c has a band shape extending in the direction along the Y axis so as to be continuous over the plurality of piezoelectric elements 56. A predetermined constant potential is supplied to the common electrode 56c.

The common electrode 56c is made of, for example, iridium (Ir). The constituent material of the common electrode 56c is not limited to iridium and may be, for example, a metal material such as titanium (Ti), platinum (Pt), aluminum (Al), nickel (Ni), gold (Au), or copper (Cu), or a conductive oxide such as lanthanum nickel oxide (LaNiO₃:LNO) or strontium ruthenium oxide (SrRuO₃:SRO). In addition, the common electrode 56c may be formed through using of one type of these metal materials alone or may be formed through using of two or more types thereof in combination in the form of a laminate or the like.

In this manner, the common electrode 56c is mainly made of an electrode material having excellent conductivity, but contains a small amount of lead. When lead is contained in the common electrode 56c as described above, the Young's modulus of the common electrode 56c can be reduced, and the adhesion between the common electrode 56c and the piezoelectric layer 56b can be improved. Hereinafter, the material constituting the common electrode 56c may be referred to as a “second electrode material”.

The common electrodes 56c described above is formed by, for example, a known film forming technique such as a sputtering method and a known processing technique using photolithography, etching, and the like after the piezoelectric layer 56b is formed. In addition, the common electrode 56c may contain lead through, for example, introducing of lead by ion implantation or forming of a film of a material containing lead, although not particularly limited thereto. In addition, a thickness of the common electrode 56c is, for example, approximately 150 nm.

In each of the above-described piezoelectric elements 56, when a voltage is applied between the individual electrode 56a and the common electrode 56c, the piezoelectric layer 56b deforms by an inverse piezoelectric effect. Here, the vibration plate 55 is connected to the piezoelectric elements 56, and the vibration plate 55 vibrates in accordance with the deformation of the piezoelectric layer 56b.

As illustrated in FIG. 5, the vibration plate 55 includes the elastic layer 55a and an insulation layer 55b, which are stacked in this order in the Z1 direction. Here, the insulation layer 55b is disposed closer to the individual electrodes 56a in a thickness direction of the vibration plate 55.

The elastic layer 55a is a film made of, for example, silicon oxide (SiO₂). The material constituting the elastic layer 55a is not limited to SiO₂ and may be, for example, a material containing one type or two or more types of elements selected from titanium (Ti), silicon (Si), aluminum (Al), tantalum (Ta), chromium (Cr), iridium (Ir), hafnium (Hf), zirconium (Zr), and carbon (C) in any state of a simple substance, an oxide, and a nitride.

A thickness of the elastic layer 55a is determined according to a thickness, a width, and the like of the vibration plate 55 and is not particularly limited, but, for example, the thickness of the elastic layer 55a is in a range of 100 nm or more and 3000 nm or less.

The insulation layer 55b is, for example, a film made of zirconium oxide (ZrO₂) and contains zirconium (Zr). Since the insulation layer 55b containing zirconium is disposed closer to the individual electrode 56a in the thickness direction of the vibration plate 55 as described above, bonding of lead contained in the individual electrode 56a to the material constituting the elastic layer 55a can be suppressed. The material constituting the insulation layer 55b is not limited to ZrO₂ and may be, for example, a material containing one type or two or more types of elements selected from titanium (Ti), aluminum (Al), tantalum (Ta), chromium (Cr), hafnium (Hf), zirconium (Zr), and silicon (Si) in any state of an oxide and a nitride.

A thickness of the insulation layer 55b is determined according to the thickness, the width, and the like of the vibration plate 55 and is not particularly limited, but, for example, the thickness of the insulation layer 55b is in a range of 100 nm or more and 2000 nm or less.

In the example illustrated in FIG. 5, the elastic layer 55a and the insulation layer 55b are in contact with each other. Another layer such as an adhesion layer for increasing the adhesion between the elastic layer 55a and the insulation layer 55b may be interposed therebetween. The material constituting the adhesion layer is, for example, TiO_{X}, AlO_{X}, CrO_{X}, or TiN. A thickness of the adhesion layer is determined according to the thickness, the width, and the like of the vibration plate 55 and is not particularly limited, but, for example, the thickness of the adhesion layer is in a range of 20 nm or more and 2000 nm or less.

The elastic layer 55a and the insulation layer 55b described above are formed in this order on a silicon single crystal substrate for forming the pressure chamber substrate 52. For example, when the elastic layer 55a is made of silicon oxide, the elastic layer 55a is formed through thermally oxidizing of one surface of the silicon single crystal substrate. For example, when the insulation layer 55b is made of zirconium oxide, the insulation layer 55b is formed through forming of a zirconium layer on the elastic layer 55a by a sputtering method and thermally oxidizing of the zirconium layer.

The method of forming each of the films constituting the vibration plate 55 is not limited to the above-described example and is selected in any desired way. For example, at least a part of the elastic layer 55a may be formed by a chemical vapor deposition (CVD) method or the like. In addition, when the adhesion layer is provided between the elastic layer 55a and the insulation layer 55b, the adhesion layer is formed through forming of a layer of chromium, titanium, aluminum, or the like on the elastic layer 55a by a sputtering method and thermally oxidizing of the layer. In this case, the thermal oxidation for forming the adhesion layer may be performed together with the thermal oxidation for forming the insulation layer 55b. In addition, the method for forming the adhesion layer is not limited to a method using thermal oxidation, and for example, a CVD method, an atomic layer deposition (ALD) method, or the like may be used.

The actuator 1 including the vibration plate 55 and the piezoelectric elements 56 described above has a vibration region PV that vibrates by driving of the piezoelectric elements 56. The vibration region PV is a part of the actuator 1 and is a portion overlapping with each pressure chamber C in plan view.

The vibration region PV is divided into an active portion RA and a non-active portion RN. The active portion RA is a part of the actuator 1 and is a portion overlapping with the pressure chamber C, the individual electrode 56a, the piezoelectric layer 56b, and the common electrode 56c when viewed in the direction along the Z axis. The non-active portion RN is a part of the actuator 1 and is a portion overlapping with the pressure chamber C when viewed in the direction along the Z axis and different from the active portion RA.

In the liquid ejecting head 50 described above, each of the individual electrode 56a and the common electrode 56c contains lead as described above.

When lead is contained in each of the individual electrode 56a and the common electrode 56c, lead has a function of improving the adhesion between the individual electrode 56a and the common electrode 56c, and the piezoelectric layer 56b, but increases a resistance value of each of the individual electrode 56a and the common electrode 56c.

Therefore, the lead content in the common electrode 56c is lower than the lead content in the individual electrode 56a. In other words, the lead content in the individual electrode 56a is higher than the lead content in the common electrode 56c. As a result, it is possible to reduce variations in the characteristics of the plurality of piezoelectric elements 56 while improving the reliability of the liquid ejecting head 50.

More specifically, since the lead content in the common electrode 56c is lower than the lead content in the individual electrode 56a, it is possible to suppress an increase in resistance value due to the lead contained in the common electrode 56c. Unlike the individual electrode 56a, the common electrode 56c is provided in a wide range in common for the plurality of piezoelectric elements 56. Therefore, as the electric resistance of the common electrode 56c increases, variations in potential of each piezoelectric element 56 are likely to occur. Therefore, through suppressing of the increase in resistance value due to the lead contained in the common electrode 56c, it is possible to obtain an effect that the variations in potential of each piezoelectric element 56 is easily reduced. In addition, since the lead content in the individual electrode 56a is higher than the lead content in the common electrode 56c, the adhesion between the individual electrode 56a and the piezoelectric layer 56b can be improved. Since the contact area between the individual electrode 56a and the piezoelectric layer 56b is smaller than the contact area between the common electrode 56c and the piezoelectric layer 56b, the individual electrode 56a is more easily peeled off from the piezoelectric layer 56b than is the common electrode 56c. Therefore, through improving of the adhesion between the individual electrode 56a and the piezoelectric layer 56b, the reliability of the piezoelectric elements 56 can be suitably improved.

In addition, since the lead content in the common electrode 56c is lower than the lead content in the individual electrode 56a, the purity of the metal material constituting the common electrode 56c can be made higher than the purity of the metal material constituting the individual electrode 56a. Specifically, the content of the metal material as the main component constituting the common electrode 56c is higher than the content of the metal material as the main component constituting the individual electrode 56a. For example, when the common electrode 56c and the individual electrode 56a are made of platinum, the content of platinum in the common electrode 56c is higher than the content of platinum in the individual electrode 56a.

In the present embodiment, the piezoelectric element 56 can be easily deformed through using of the common electrode 56c, which is superior in ductility to the individual electrode 56a by its metal purity, as the upper electrode.

When the lead content in the individual electrode 56a is α [atm %] and the lead content in the common electrode 56c is β [atm %], β/α corresponds to the peak intensity ratio measured by energy dispersive X-ray spectrometry (EDS) or secondary ion mass spectrometry (SIMS). Here, the peak intensity ratio is calculated by comparison of the peak values indicating lead in the individual electrode 56a and the common electrode 56c. When the individual electrode 56a or the common electrode 56c does not indicate a peak, a portion of the individual electrode 56a or the common electrode 56c indicating a broad shoulder is treated as a peak. In addition, when the individual electrode 56a or the common electrode 56c indicates both a peak and a shoulder, one of the peak and the shoulder is treated as a peak.

In addition, when the lead content in each of the piezoelectric layer 56b and the common electrode 56c is measured by energy dispersive X-ray spectrometry, the peak value indicating lead in the common electrode 56c is smaller than the peak value indicating lead in the piezoelectric layer 56b.

FIG. 6 is an enlarged view of a portion VI in FIG. 5. As illustrated in FIG. 6, the piezoelectric layer 56b includes a plurality of layers LA-1 to LA-5 made of a piezoelectric material. Hereinafter, each of the layers LA-1 to LA-5 may be referred to as a layer LA without being distinguished. The number of layers LA constituting the piezoelectric layer 56b is not limited to the example illustrated in FIG. 6 and may be four or less or six or more. In addition, a thickness of the plurality of layers LA may be equal to or different from each other. In FIG. 6, for convenience of description, an interface between two layers adjacent to each other is clearly illustrated, but the interface does not have to be clear due to an inclined material configuration or the like.

As illustrated in FIG. 6, each piezoelectric element 56 includes the first mixed layer 56d, the second mixed layer 56e, and the lead diffusion suppression layer 56f in addition to the individual electrode 56a, the piezoelectric layer 56b, and the common electrode 56c described above. The lead diffusion suppression layer 56f may be regarded as a component of the vibration plate 55 instead of a component of the piezoelectric element 56, or may be regarded as a component separate from the piezoelectric element 56 and the vibration plate 55.

The first mixed layer 56d is disposed between the individual electrode 56a and the piezoelectric layer 56b and is made of a material in which the first electrode material constituting the individual electrode 56a and lead are mixed or alloyed. Through providing of the first mixed layer 56d described above, it is possible to improve the adhesion between the individual electrode 56a and the piezoelectric layer 56b. As a result, the effect obtained through making of the lead content in the individual electrode 56a higher than the lead content in the common electrode 56c can be remarkably obtained.

It is preferable that the first mixed layer 56d includes a first adhesion material that assists adhesion between the individual electrode 56a and the piezoelectric layer 56b, and the first adhesion material, the first electrode material, and lead are mixed or alloyed. Accordingly, the adhesion between the individual electrode 56a and the piezoelectric layer 56b can be improved.

Examples of the first adhesion material include metals such as Ti and Ir, and metal oxides such as TiO_{X}, ZnO_{X}, AlO_{X}, ZrO_{X}, HfO_{X}, TaO_{X}, IrO_{X}, RuO_{X}, VO_{X}, SrRuO_{X}, SrTaO_{X}, LaTaO_{X}, and (LaSr)CoO_{X}.

The first adhesion material preferably contains titanium oxide (TiO_{X}) as a constituent element. Accordingly, through increasing of the oxygen concentration in the first mixed layer 56d, a redox reaction in the first mixed layer 56d can be suppressed. As a result, oxygen release from the piezoelectric layer 56b can be suppressed. Specifically, according to the Ellingham diagram, when Pb and Ti are compared, PbO is easily reduced to Pb, and Ti is easily oxidized to TiO_{X}. Therefore, when the titanium concentration in the first mixed layer 56d is high, since the redox reaction can be suppressed, it is possible to suppress the release of oxygen from the piezoelectric layer 56b and the reduction of lead zirconate titanate.

A specific thickness t1 of the first mixed layer 56d is not particularly limited, but is, for example, in a range of 20 nm or more and 80 nm or less. The first mixed layer 56d is provided as necessary and may be omitted.

The second mixed layer 56e is disposed between the common electrode 56c and the piezoelectric layer 56b and is made of a material in which the second electrode material constituting the common electrode 56c and lead are mixed or alloyed. Through providing of the second mixed layer 56e described above, it is possible to improve the adhesion between the common electrode 56c and the piezoelectric layer 56b.

It is preferable that the second mixed layer 56e includes a second adhesion material that assists adhesion between the common electrode 56c and the piezoelectric layer 56b, and the second adhesion material, the second electrode material, and lead are mixed or alloyed. Accordingly, the adhesion between the common electrode 56c and the piezoelectric layer 56b can be improved.

Similarly to the first adhesion material, examples of the second adhesion material include metals such as Ti and Ir, and metal oxides such as TiO_{X}, ZnO_{X}, AlO_{X}, ZrO_{X}, HfO_{X}, TaO_{X}, IrO_{X}, RuO_{X}, VO_{X}, SrRuO_{X}, SrTaO_{X}, LaTaO_{X}, and (LaSr)CoO_{X}.

The second adhesion material preferably contains titanium oxide (TiO_{X}) as a constituent element. Accordingly, through increasing of the oxygen concentration in the second mixed layer 56e, a redox reaction in the second mixed layer 56e can be suppressed. As a result, oxygen release from the piezoelectric layer 56b can be suppressed.

A specific thickness t2 of the second mixed layer 56e is not particularly limited, but is, for example, in a range of 20 nm or more and 80 nm or less. The second mixed layer 56e is provided as necessary and may be omitted. In addition, the relationship between the thickness t2 of the second mixed layer 56e and the thickness t1 of the first mixed layer 56d in terms of size is not particularly limited.

The lead diffusion suppression layer 56f is disposed between the individual electrode 56a and the vibration plate 55. Through providing of the lead diffusion suppression layer 56f described above, penetration of lead into the vibration plate 55 can be suppressed.

The lead diffusion suppression layer 56f includes, for example, an oxide or a nitride of at least one element of zirconium (Zr), strontium (Sr), ruthenium (Ru), bismuth (Bi), iron (Fe), titanium (Ti), chromium (Cr), lead (Pb) hafnium (Hf), iridium (Ir), rhodium (Rh), osmium (Os), and silicon (Si). Accordingly, penetration of lead from the lower electrode into the vibration plate 55 can be suppressed.

The lead diffusion suppression layer 56f preferably contains one or both of zirconium and silicon. Accordingly, there is an advantage that the adhesion between the individual electrode 56a and the vibration plate 55 is easily increased.

A thickness of the lead diffusion suppression layer 56f is not particularly limited, but is, for example, in a range of 1 nm or more and 10 nm or less. The lead diffusion suppression layer 56f is provided as necessary and may be omitted.

### 2. Second Embodiment

Hereinafter, a second embodiment of the present disclosure will be described. In the embodiment, which will be exemplified below, elements having operations and functions similar to those in the first embodiment are denoted by the same reference signs as those used in the description of the first embodiment, and detailed description thereof will be appropriately omitted.

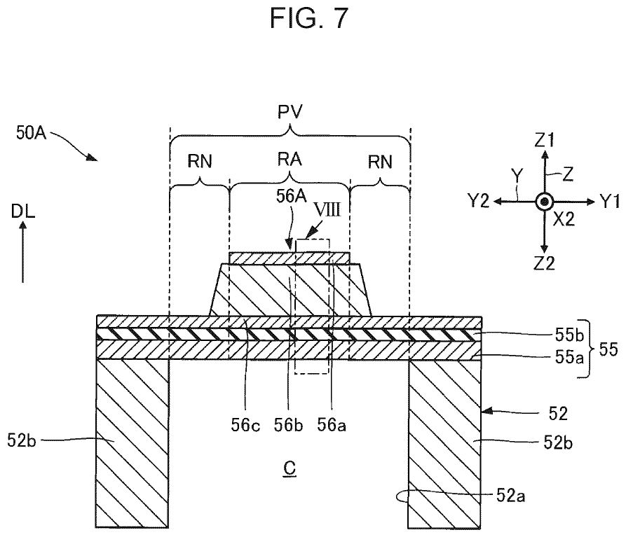

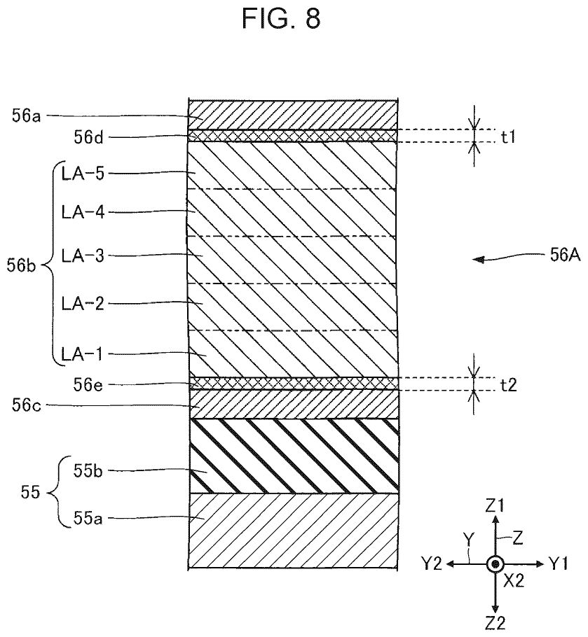

FIG. 7 is a sectional view of a liquid ejecting head 50A according to the second embodiment. FIG. 8 is an enlarged view of a portion VIII in FIG. 7. The liquid ejecting head 50A is configured in the same manner as the liquid ejecting head 50 of the first embodiment except that the liquid ejecting head 50A includes a piezoelectric element 56A instead of the piezoelectric element 56 of the first embodiment.

As illustrated in FIGS. 7 and 8, the piezoelectric element 56A is configured in the same manner as the piezoelectric element 56 of the first embodiment except that the stacking order is opposite to that of the piezoelectric element 56 of the first embodiment, and the lead diffusion suppression layer 56f is omitted. In FIG. 7, for convenience of description, the first mixed layer 56d and the second mixed layer 56e are not illustrated. The piezoelectric element 56A may have the lead diffusion suppression layer 56f.

As illustrated in FIG. 8, in the present embodiment, the vibration plate 55, the common electrode 56c, the piezoelectric layer 56b, and the individual electrode 56a are stacked in order in the stacking direction DL. Here, the first mixed layer 56d is disposed between the individual electrode 56a and the piezoelectric layer 56b. The second mixed layer 56e is disposed between the common electrode 56c and the piezoelectric layer 56b. Hereinafter, in the present embodiment, the common electrode 56c may be referred to as a “lower electrode”, and the individual electrode 56a may be referred to as an “upper electrode”.

In this configuration as well, the lead content in the common electrode 56c is lower than the lead content in the individual electrode 56a. In other words, the lead content in the individual electrode 56a is higher than the lead content in the common electrode 56c.

In addition, in the present embodiment as well, the piezoelectric layer 56b includes the plurality of layers LA. Here, as described above, since the vibration plate 55, the common electrode 56c, the piezoelectric layer 56b, and the individual electrode 56a are stacked in order in the stacking direction DL, when the piezoelectric layer 56b is formed by film formation, the concentration of lead may be different in the plurality of layers LA. As a result, excessive lead may remain in the uppermost layer LA-5 among the plurality of layers LA of the piezoelectric layer 56b, and lead may be released to the outside. According to this configuration, since the individual electrode 56a, which is the upper electrode having a high lead content, covers the piezoelectric layer 56b, it is possible to suppress the release of lead from the piezoelectric layer 56b to the outside at the time of firing in consideration of the balance between the piezoelectric layer 56b and the individual electrode 56a.

According to the second embodiment described above, similarly to the first embodiment, it is possible to reduce the variations in the characteristics of a plurality of the piezoelectric elements 56A while improving the reliability of the piezoelectric elements 56A.

### 3. Modifications

The embodiments exemplified above can be modified in various ways. Specific modification aspects that can be applied to the above-described embodiments will be exemplified below. Two or more aspects freely selected from the following examples can be appropriately combined within a range in which the two or more aspects do not contradict each other.

### 3-1. Modification 1

In each of the above-described embodiments, the piezoelectric layer 56b is provided in common for the plurality of pressure chambers C, but the present disclosure is not limited thereto, and the piezoelectric layer 56b may be divided for each pressure chamber C.

### 3-2. Modification 2

Each of the above-described embodiments describes the serial-type liquid ejecting apparatus 100 in which the carriage 41 having the liquid ejecting head 50 mounted therein is reciprocated, but the present disclosure may also be applied to a line-type liquid ejecting apparatus in which the plurality of nozzles N is distributed over the entire width of the medium M.

### 3-3. Modification 3

The liquid ejecting apparatus 100 described in each of the above-described embodiments may be employed in various apparatuses such as facsimile machines and copying machines in addition to apparatuses dedicated to printing. Moreover, the application of the liquid ejecting apparatus of the present disclosure is not limited to printing. For example, a liquid ejecting apparatus that ejects a solution of a coloring material is used as a manufacturing device that forms color filters of a liquid crystal display device. In addition, a liquid ejecting apparatus that ejects a solution of a conductive material is used as a manufacturing device that forms wiring lines or electrodes of a wiring substrate.

### 4. Summary of Present Disclosure

A summary of the present disclosure is added below.

### Supplementary Note 1

According to a first aspect of the present disclosure, there is provided a liquid ejecting head including a piezoelectric element including an individual electrode, a piezoelectric layer, and a common electrode, and a vibration plate connected to the piezoelectric element, in which the individual electrode is individually provided for each of a plurality of piezoelectric elements, the common electrode is provided in common for the plurality of piezoelectric elements, the piezoelectric layer is made of a piezoelectric material containing lead as a constituent element, each of the individual electrode and the common electrode contains lead, and a lead content in the common electrode is lower than a lead content in the individual electrode.

In the above aspect, since the lead content in the common electrode is lower than the lead content in the individual electrode, it is possible to suppress an increase in resistance value due to the lead contained in the common electrode. Unlike the individual electrode, the common electrode is provided in a wide range in common for the plurality of piezoelectric elements. Therefore, as the electric resistance of the common electrode increases, variations in potential of each piezoelectric element are likely to occur. Therefore, through suppressing of the increase in resistance value due to the lead contained in the common electrode, it is possible to obtain an effect that the variations in potential of each piezoelectric element is easily reduced. In addition, since the lead content in the individual electrode is higher than the lead content in the common electrode, the adhesion between the individual electrode and the piezoelectric layer can be improved. Since the contact area between the individual electrode and the piezoelectric layer is smaller than the contact area between the common electrode and the piezoelectric layer, the individual electrode is more easily peeled off from the piezoelectric layer than is the common electrode. Therefore, through improving of the adhesion between the individual electrode and the piezoelectric layer, the reliability of the piezoelectric elements can be suitably improved.

When lead is contained in each of the individual electrode and the common electrode, lead has a function of improving the adhesion between the individual electrode and the common electrode, and the piezoelectric layer, but increases a resistance value of each of the individual electrode and the common electrode. Therefore, as described above, through making of the lead content in the common electrode lower than the lead content in the individual electrode, it is possible to reduce the variations in the characteristics of the plurality of piezoelectric elements while improving the reliability of the piezoelectric elements.

### Supplementary Note 2

In a second aspect that is a preferred example of the first aspect, the liquid ejecting head further includes a first mixed layer that is disposed between the individual electrode and the piezoelectric layer and in which a first electrode material constituting the individual electrode and lead are mixed or alloyed. In the above aspect, it is possible to improve the adhesion between the individual electrode and the piezoelectric layer. As a result, the effect obtained through making of the lead content in the individual electrode higher than the lead content in the common electrode can be remarkably obtained.

### Supplementary Note 3

In a third aspect that is a preferred example of the second aspect, the first mixed layer includes a first adhesion material that assists adhesion between the individual electrode and the piezoelectric layer, and the first adhesion material, the first electrode material, and lead are mixed or alloyed. In the above aspect, it is possible to improve the adhesion between the individual electrode and the piezoelectric layer.

### Supplementary Note 4

In a fourth aspect that is a preferred example of the third aspect, the first adhesion material contains titanium oxide as a constituent element. In the above aspect, through increasing of the oxygen concentration in the first mixed layer, a redox reaction in the first mixed layer can be suppressed. As a result, oxygen release from the piezoelectric layer can be suppressed.

### Supplementary Note 5

In a fifth aspect that is a preferred example of any one of the first to fourth aspects, the liquid ejecting head further includes a second mixed layer that is disposed between the common electrode and the piezoelectric layer and in which a second electrode material constituting the common electrode and lead are mixed or alloyed. In the above aspect, it is possible to improve the adhesion between the common electrode and the piezoelectric layer.

### Supplementary Note 6

In a sixth aspect that is a preferred example of any one of the first to fifth aspects, the liquid ejecting head further includes a lead diffusion suppression layer disposed between the individual electrode and the vibration plate, and the vibration plate, the individual electrode, the piezoelectric layer, and the common electrode are stacked in order in a stacking direction. In the above aspect, penetration of lead into the vibration plate can be suppressed. In addition, through using of the common electrode, which is superior in ductility to the individual electrode by its metal purity, as the upper electrode, the piezoelectric element can be easily deformed.

### Supplementary Note 7

In a seventh aspect that is a preferred example of the sixth aspect, the lead diffusion suppression layer contains one or both of zirconium and silicon. In the above aspect, there is an advantage that the adhesion between the individual electrode and the vibration plate is easily increased.

### Supplementary Note 8

In an eighth aspect that is a preferred example of any one of the first to fifth aspects, the vibration plate, the common electrode, the piezoelectric layer, and the individual electrode are stacked in order in a stacking direction, and the piezoelectric layer includes a plurality of layers made of the piezoelectric material. In the above aspect, since the upper electrode having a high lead content covers the piezoelectric layer, it is possible to suppress the release of lead from the piezoelectric layer to the outside at the time of firing in consideration of the balance between the piezoelectric layer and the upper electrode.

What is claimed is:

1. A liquid ejecting head comprising:
a piezoelectric element including an individual electrode, a piezoelectric layer, and a common electrode; and
a vibration plate, wherein
the individual electrode is individually provided for each of a plurality of piezoelectric elements,
the common electrode is provided in common for the plurality of piezoelectric elements,
the piezoelectric layer is made of a piezoelectric material containing lead as a constituent element,
each of the individual electrode and the common electrode contains lead, and
a lead content in the common electrode is lower than a lead content in the individual electrode.

2. The liquid ejecting head according to claim 1, further comprising
a first mixed layer that is disposed between the individual electrode and the piezoelectric layer and in which a first electrode material constituting the individual electrode and lead are mixed or alloyed.

3. The liquid ejecting head according to claim 2, wherein
the first mixed layer includes a first adhesion material that assists adhesion between the individual electrode and the piezoelectric layer, and
the first adhesion material, the first electrode material, and lead are mixed or alloyed.

4. The liquid ejecting head according to claim 3, wherein
the first adhesion material contains titanium oxide as a constituent element.

5. The liquid ejecting head according to claim 2, further comprising
a second mixed layer that is disposed between the common electrode and the piezoelectric layer and in which a second electrode material constituting the common electrode and lead are mixed or alloyed.

6. The liquid ejecting head according to claim 1, further comprising
a lead diffusion suppression layer disposed between the individual electrode and the vibration plate, wherein
the vibration plate, the individual electrode, the piezoelectric layer, and the common electrode are stacked in order in a stacking direction.

7. The liquid ejecting head according to claim 6, wherein
the lead diffusion suppression layer contains one or both of zirconium and silicon.

8. The liquid ejecting head according to claim 1, wherein
the vibration plate, the common electrode, the piezoelectric layer, and the individual electrode are stacked in order in a stacking direction, and
the piezoelectric layer includes a plurality of layers made of the piezoelectric material.

9. The liquid ejecting head according to claim 5, wherein
the vibration plate, the common electrode, the piezoelectric layer, and the individual electrode are stacked in order in a stacking direction, and
the piezoelectric layer includes a plurality of layers made of the piezoelectric material.

10. The liquid ejecting head according to claim 1, wherein
the vibration plate, the individual electrode, the piezoelectric layer, and the common electrode are stacked in order in a stacking direction, and
the piezoelectric layer includes a plurality of layers made of the piezoelectric material.

11. A liquid ejecting head comprising:
a first piezoelectric element which includes a first individual electrode, a first piezoelectric layer, and a common electrode;
a second piezoelectric element which includes a second individual electrode, a second piezoelectric layer, and the common electrode; and
a vibration plate, wherein
the first piezoelectric layer is made of a piezoelectric material containing lead as a constituent element,
each of the first individual electrode and the common electrode contains lead, and
a lead content in the common electrode is lower than a lead content in the first individual electrode.
